(19) United States
(12) Patent Application Publication
(10) Pub. No.: US 2005/0076277 A1
(43) Pub. Date: Apr. 7, 2005

(54) Test apparatus with static storage device and test method

(76) Inventor: Erwin Thalmann, Villach (AT)

Correspondence Address: JENKINS & WILSON, PA, 3100 TOWER BLVD, SUITE 1400, DURHAM, NC, 27707, US

(21) Appl. No.: 10/947,564

(22) Filed: Sep. 22, 2004

(30) Foreign Application Priority Data
Oct. 2, 2003 (DE) 10345974.6

(51) Int. Cl. G01R 31/28; G06F 11/00

(52) U.S. Cl. 714/724

(57) ABSTRACT

The invention provides a test apparatus for testing circuit units (101) to be tested by means of a test system, a circuit unit (101) to be tested having a register device (114), in which it is possible to store initialization data (115) that are fed by means of a storage signal (110), a control unit (102) for controlling a storage of the initialization data (115) and a switch-on unit (103) for switching on the at least one circuit unit (101) to be tested, a static storage device (201) for nonvolatile storage of the initialization data (115) that are fed by means of the storage signal (110) further being arranged in the circuit unit (101) to be tested.

The present invention generally relates to a testing of circuit units to be tested, and in particular relates to a method for testing circuit units to be tested in which initialization data are stored in at least one register device of the circuit unit to be tested.

Specifically, the present invention relates to a test apparatus for testing circuit units to be tested by means of a test system, a circuit unit to be tested having a register device, in which it is possible to store initialization data that are fed by means of a storage signal, a control unit for controlling a storage of the initialization data in the register device by means of a storage control signal, and a switch-on unit for switching on the at least one circuit unit to be tested.

The method according to the present invention comprises a switch-on of the at least one circuit unit to be tested by means of a switch-on unit, a storage of initialization data that are fed by means of a storage signal in a register device of the circuit unit to be tested, a control of a storage of the initialization data in the register device by means of a storage control signal provided by a control unit, and a testing of the circuit unit to be tested by means of a test procedure prescribed by the test system.

When testing circuit units to be tested, the circuit units to be tested being in particular memory modules or chips, it is becoming increasingly more important to keep test costs at a low level. The test costs are determined in particular by the number of circuit units to be tested which can be tested in a predetermined time.

A quotient resulting on a number of circuit units to be tested per test duration determined is referred to as a throughput rate. In order to lower test costs, it is possible, then, either to reduce the test time or to increase the number of circuit units to be tested which can be tested in parallel per test system.

While there are numerous proposals for increasing a parallelism when testing circuit units to be tested, the actual test times when testing circuit units to be tested can only be reduced by a specific reduction of process steps.

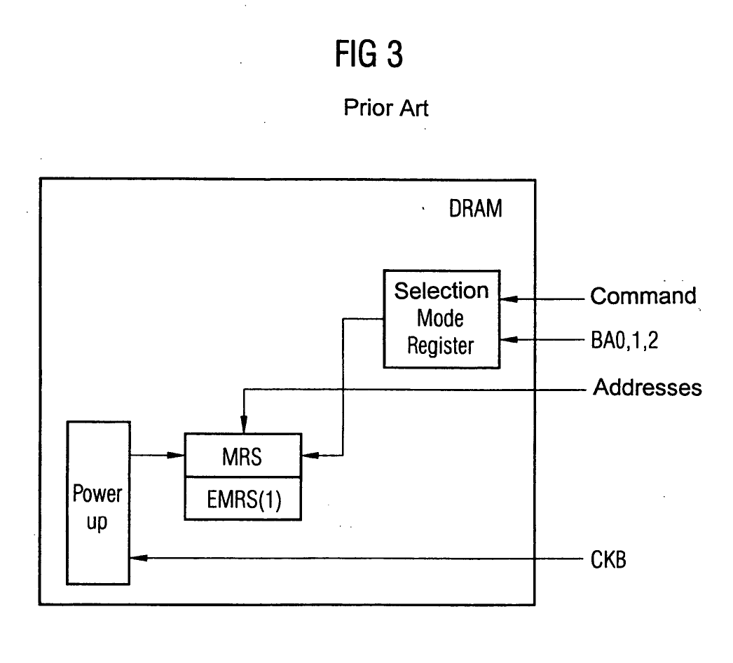

FIG. 3 shows a conventional circuit unit to be tested, formed as a DRAM memory. It should be pointed out that FIG. 3 shows the essential components necessary for testing the circuit unit to be tested. Thus, a selection mode register receives a command used to control a storage of initialization values that are fed via the terminal “Addresses”. Furthermore, various register banks can be addressed with the aid of the selection mode register, which are designated by BA0, 1, 2 in FIG. 3.

Consequently, it is possible for the circuit unit to be tested to be initialized into a predetermined basic state by the setting of predeterminable initialization values in specific registers, for example the mode register MRS shown or the extended mode register (1), designated as EMRS (1). Depending on a clock signal fed via the input “CKI”, a switch-on “power up” is effected and a testing of the circuit unit to be tested can begin. It is inexpedient that the initialization values stored in the registers MRS, EMRS (1) etc. are not preserved if the circuit unit—DRAM—to be tested is switched off. However, when testing circuit units to be tested, in particular in the case of DRAMs (Dynamic Random Access Memory), it is necessary to perform many tests at different temperatures and with other ambient states. In this case, it is necessary to disconnect a supply voltage before each test, in such a way that the initialization values stored in the registers MRS; EMRS (1) etc., are disadvantageously lost.

It is inexpedient, therefore, that in the event of each test to be carried out, new initialization data have to be written to the registers MRS, EMRS (1) etc., which considerably increases an overall test time portion in an inexpedient manner.

It is an essential disadvantage of conventional circuit units to be tested, illustrated with reference to FIG. 3, that a basic setting of registers can be performed anew in the event of each test in such a way that a throughput rate defined above is lowered. This inexpediently leads to high test costs.

DE 100 24 636 discloses a method for the nonvolatile storage of at least one operating data value of an electric motor, provision being made of a nonvolatile memory in which initialization values are stored, which, in the event of the electric motor being switched on again—after the electric motor has been switched off—take an old operating data value from the nonvolatile memory.

It is disadvantageous that the apparatus described in DE 100 24 636 merely stores an operating data value which furthermore constitutes only a dynamic state value. It is inexpedient that it is furthermore necessary to provide a dedicated memory for storing the operating data value, which is not integrated in existing circuit devices.

Consequently, it is an object of the present invention to reduce the test times required for an initialization of the circuit units to be tested and to lower test costs.

This object is achieved according to the invention by means of an apparatus having the features of Patent Claim 1. Furthermore, the object is achieved by means of a method specified in Patent Claim 8. Further refinements of the invention emerge from the subclaims.

An essential concept of the invention consists in permanently storing basic settings of registers in nonvolatile storage units that are additionally provided as static storage devices in the circuit unit to be tested. For this purpose, the circuit unit to be tested is extended with a static storage device, in such a way that the initialization data for testing the circuit unit to be tested are preserved even in the event of a disconnection of the supply voltage and can be provided for a subsequent test.

Consequently, it is an advantage of the present invention that the test costs can be drastically reduced by virtue of reducing the test times by shortening an initialization procedure.

The initialization procedure is shortened by virtue of the initialization data—provided that the latter do not differ from a preceding test procedure—not having to be written anew to the circuit unit to be tested. The register contents of the static storage device of the circuit unit to be tested can advantageously be used repeatedly in succession for carrying out different test procedures. It is furthermore expedient that the apparatus according to the invention provides an extension by a static storage device, which does not lead to any change in a conventional test operation or conventional test procedures. It is advantageous that only a setting of register contents is dispensed with, since this setting of register contents is carried out within the circuit unit to be tested.

According to the invention, the circuit unit to be tested in a test apparatus by means of a test system essentially has:
a) a register device, in which it is possible to store initialization data that are fed by means of a storage signal;
b) a control unit for controlling a storage of the initialization data in the register device by means of a storage control signal; and
c) a switch-on unit for switching on the at least one circuit unit to be tested,
   in which case the circuit unit to be tested is provided with a static storage apparatus for nonvolatile storage of the initialization data that are fed by means of the storage signal and can be stored in the register device.

Furthermore, the method according to the invention for testing circuit units to be tested by means of a test system essentially has the following steps:
a) switch-on of the at least one circuit unit to be tested by means of a switch-on unit;
b) storage of initialization data that are fed by means of a storage signal in a register device of the circuit unit to be tested;
c) control of a storage of the initialization data in the register device by means of a storage control signal provided by a control unit; and
d) testing of the circuit units to be tested by means of a test procedure prescribed by the test system,
   the initialization data that are fed by means of the storage signal being stored in nonvolatile fashion by means of a static storage device.

In accordance with one preferred development of the present invention, the register device comprises a mode register unit in which mode register signals can be stored. It is furthermore expedient that the register device comprises at least one extended mode register unit for storing extended mode register signals.

In accordance with a further preferred development of the present invention, the circuit unit to be tested is formed as a DRAM memory (Dynamic Random Access Memory).

In accordance with yet another preferred development of the present invention, the static storage device for nonvolatile storage of the initialization data that are fed by means of the storage signal is constructed identically to the register device of the circuit unit to be tested.

In accordance with yet another preferred development of the present invention, the static storage device has a mode register buffer storage unit for buffer-storing mode register initialization data. The buffer-stored mode register initialization data are transmitted to the mode register unit of the circuit unit to be tested when the circuit unit to be tested is switched on.

In accordance with yet another preferred development of the present invention, the static storage device has at least one extended mode register buffer storage unit for buffer-storing extended mode register initialization data.

It is advantageous that when the circuit unit to be tested is switched on, the extended mode register initialization data are transmitted from the extended mode register buffer storage unit of the static storage apparatus to the extended mode register unit of the circuit unit to be tested.

In accordance with yet another preferred development of the present invention, the initialization data stored in the static storage device are transmitted directly into the register device in the event of a second and further test procedures for testing the circuit unit to be tested.

In accordance with yet another preferred development of the present invention, the static storage device stores the initialization data that are fed by means of the storage signal in nonvolatile fashion and in a manner arranged identically to the storage in the register device.

In accordance with yet another preferred development of the present invention, initialization signals are fed to the register device from the static storage device after the circuit unit to be tested has been switched on by means of the switch-on unit.

In accordance with yet another preferred development of the present invention, the storage signal fed to the circuit unit to be tested via a storage signal terminal unit is mirrored into the static storage device.

In accordance with yet another preferred development of the present invention, the register device is automatically set after the circuit unit to be tested has been switched on.

In accordance with yet another preferred development of the present invention, the static storage device for nonvolatile storage of the initialization data that are fed by means of the storage signal and can be stored in the register device is controlled by means of the storage control signal.

Exemplary embodiments of the invention are illustrated in the drawings and are explained in more detail in the description below.

In the drawings:

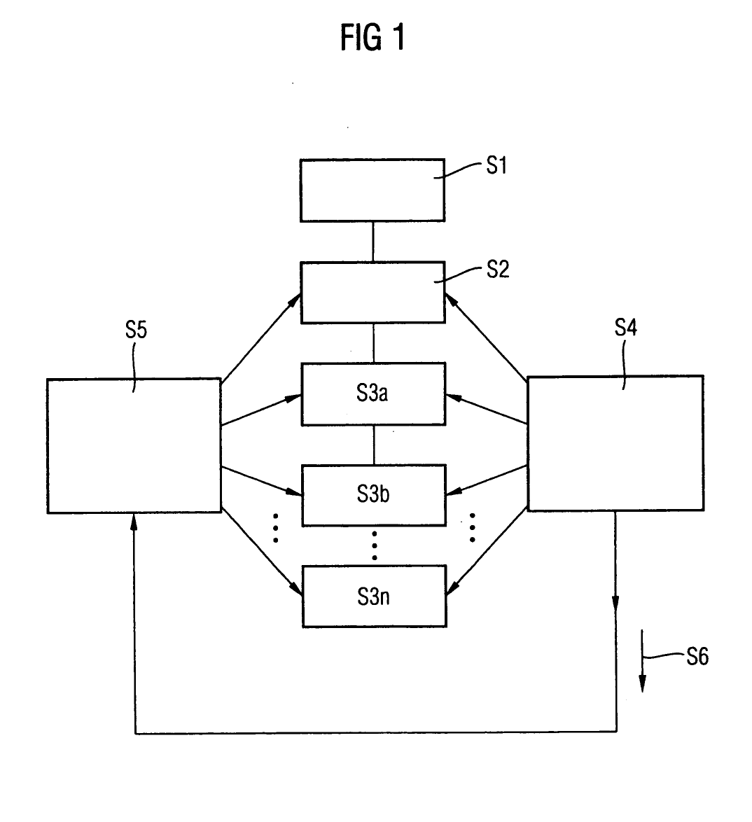

FIG. 1 shows a flowchart for elucidating the method according to the invention for testing circuit units to be tested in accordance with a preferred exemplary embodiment;

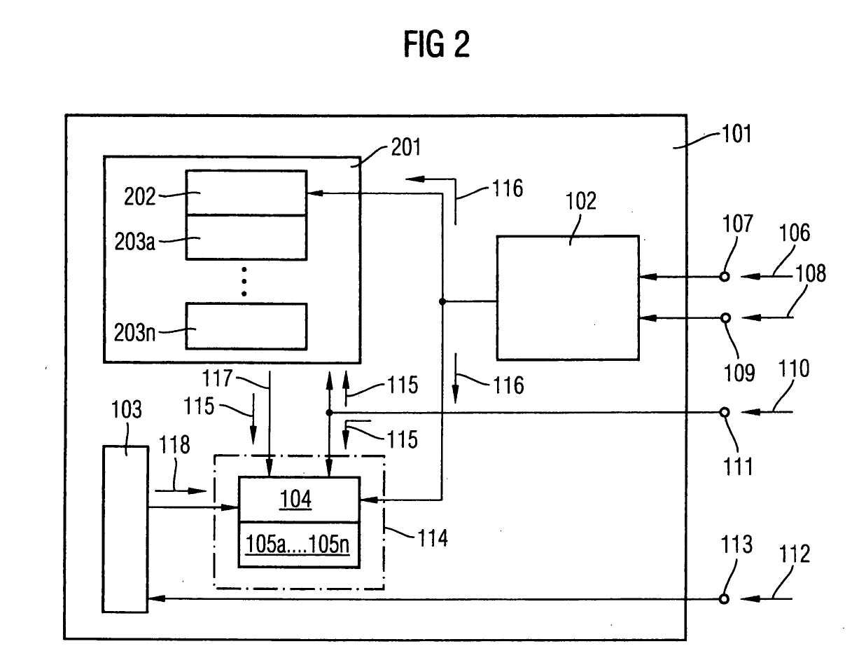

FIG. 2 shows a block diagram of a circuit unit to be tested by means of a test system with a register device and a static storage device in accordance with a preferred exemplary embodiment of the present invention; and

FIG. 3 shows a conventional circuit unit to be tested by means of a test system.

In the figures, identical reference symbols designate identical or functionally identical components or steps.

FIG. 1 shows a flowchart for writing initialization data to register units of at least one register device of a circuit unit to be tested, for elucidating a preferred embodiment of the present invention. The circuit unit 101 to be tested, which will be described below with reference to FIG. 2, is switched on in a switch-on step S1.

A mode register unit 104 is initialized in a subsequent mode register initialization step. Extended mode register units 105a-105n (described below with reference to FIG. 2) are subsequently initialized in succeeding extended mode register initialization steps S3a-S3n.

It should be pointed out that a predeterminable number of extended mode register units can be initialized by a corresponding number of extended mode register initialization steps S3a-S3n.

In the event of a first switch-on of the circuit unit to be tested, after the step S1, the initialization data are input by means of an external initialization value input step S4 with respect to the mode register initialization step S2 and the extended mode register initialization steps S3a-S3n.

According to the invention, in the event of a first initialization of the circuit unit to be tested, the external initialization value input step furthermore performs a static, i.e. permanent, storage of initialization data in a static storage device 201 described below with reference to FIG. 2.

If a further switch-on of the circuit unit 101 to be tested is performed by the switch-on step S1, then the data can be initialized in an internal initialization value input step S5 directly by means of a read-out of data from the internal, static storage device 201. For this purpose, provision is made for an initialization value transfer step S6, which transfers to the internal memory the initialization data read in during an external initialization value input step S4, in order that said data are available during an internal initialization value input step S5.

A block diagram of a preferred embodiment of a circuit unit 101 to be tested will be described below with reference to FIG. 2.

FIG. 2 shows that the circuit unit 101 to be tested has a register device 114 and a static storage device 201. It should be pointed out that only those terminal units which are necessary for carrying out the method according to the invention are indicated. Thus, the circuit unit 101 to be tested has a control terminal unit 107, a bank addressing signal terminal unit 109, a storage signal terminal unit 111 and a clock signal terminal unit 113. The circuit unit 101 to be tested is switched on in a manner dependent on a clock signal 112 that is fed via the clock signal terminal unit 113 and is fed to a switch-on unit 103.

A storage signal 110, which is fed to the circuit unit 101 to be tested via the storage signal terminal unit 111, supplies an initialization signal 112 in such a way that initialization data can be fed and stored both in a register device 114 and in a static storage device 201 of the circuit unit 101 to be tested. As in conventional circuit units 101 to be tested, the register device 114 has at least one mode register unit 104 and at least one extended mode register unit 105a-105n.

According to the invention, a static storage device 201, in which initialization data that are fed by means of the initialization signal 115 can be stored statically, i.e. permanently, is provided in addition to the register device 114. The static storage device 201 according to the invention has at least one mode register buffer storage unit 202 and at least one extended mode register buffer storage unit 203a-203n.

In accordance with the preferred exemplary embodiment of the present invention that is shown here, the initialization data that are fed by means of the initialization signal 115 and are fed to the register device 114 are mirrored in the static storage device 201. Such a mirroring of the initialization data preferably takes place in the event of a first switch-on or start-up (power-up) of the circuit unit 101 to be tested.

The presettings of the mode register unit 104 and of the at least one extended mode register unit 105a-105n can be accepted during subsequent tests directly from the static storage device and the corresponding assigned buffer storage units.

In the exemplary embodiment shown, the mode register buffer storage unit 202 is assigned to the mode register unit 104, while the at least one extended mode register buffer storage unit 203a-203n is assigned to the at least one extended mode register unit 105a-105n. Via an internal transmission channel 117 of the circuit unit 101 to be tested, which transmission channel connects the static storage device 201 to the register device 114, the register device 114 or the mode register unit 104 and the at least one extended mode register unit 105a-105n are fed initialization data 115 as basic setting data from the static storage device 201 via the internal transmission channel 117.

In this way, it is possible, when testing circuit units 101 to be tested, to entirely obviate a time duration which for an initialization of the circuit unit 101 to be tested by the feeding of a storage signal 110, for example. This affords the advantage of lowering test costs.

A control unit 102 provided in the circuit unit 101 to be tested drives, on the one hand, the static storage device 201 and, on the other hand, the register device 114 in each case with storage control signals 116. The storage control signals 116 contain items of information about an addressing of specific banks and/or a control of a storage of initialization data in the static storage device 201 and the register device 114.

For this purpose, the control unit 102 is fed a control signal 106, on the one hand, via the control terminal unit 107 and a bank addressing signal 108, on the other hand, via the bank addressing signal terminal unit 109. Depending on the clock signal 112 fed via the clock signal terminal unit 113, the switch-on unit 103 outputs an acceptance signal 118 to the register device 114. The acceptance signal 118, which is provided for example when the clock signal 112 undergoes transition to a high level, has the effect that initialization data in the form of the initialization signal 115 are accepted into the register device 114 from the static storage device 201 via the internal transmission channel 117.

It should be pointed out that the method according to the invention and the apparatus according to the invention can be expediently used in particular when the initialization data that are written to the static storage device 201 during a preceding testing of the circuit unit 101 to be tested are used for subsequent tests of the circuit unit 101 to be tested.

When testing circuit units to be tested, it has been found that approximately 80% of the setting data that have to be fed in the form of initialization data to the mode register unit 104 and the at least one extended mode register unit 105a-105n remain identical. In this way, a considerable test time can be saved during each initialization of the circuit unit 101 to be tested, which leads to cost reductions when testing circuit units to be tested.

It is advantageous that the register values of the mode register unit 104 and of the at least one extended mode register unit 105a-105n may not be reloaded every time, but rather are accepted automatically from the static storage device 201 when the circuit unit 101 to be tested is switched on.

In particular, it is an advantage of the apparatus according to the invention that register values in the circuit unit to be tested are preserved at a defined state/value permanently in the static storage device 201. Furthermore, it is an advantage of the present invention that a throughput rate, i.e. the number of circuit units to be tested relative to the test time, is considerably increased, which leads to more efficient testing and to a reduction of the test costs.

It is advantageous that initialization data are preserved in the static storage device 201 even without a supply energy in the circuit unit 101 to be tested. The initialization data stored in the static storage device 201 advantageously correspond to a copy of the initialization data stored in the register device 114 in the case where the circuit unit 101 to be tested is switched on.

The circuit unit 101 to be tested that is extended by the static storage device 201 according to the invention has the essential advantage that a test time can be saved in particular when identical register contents or initialization data are repeatedly used successively. Moreover, it is expedient that such an extension of the circuit unit 101 to be tested by the static storage device 201 does not lead to any changed operating modes outside the circuit unit 101 to be tested, i.e. it is not necessary to change a conventional operation. It is advantageous that a setting of register contents or initialization data by the test system is no longer necessary since this is done internally via the internal transmission channel 117.

With regard to the conventional arrangement of a circuit unit (DRAM) to be tested as illustrated in FIG. 3, reference is made to the introduction to the description.

Although the present invention has been described above on the basis of preferred exemplary embodiments, it is not restricted thereto, but rather can be modified in diverse ways.

Moreover, the invention is not restricted to the application possibilities mentioned.

1. Test apparatus for testing a circuit unit to be tested by means of a test system, the circuit unit to be tested having:
a) a register device, in which it is possible to store initialization data that are fed by means of a storage signal;
b) a control unit for controlling a storage of the initialization data in the register device by means of a storage control signal; and
c) a switch-on unit for switching on the circuit unit to be tested,
wherein the circuit unit to be tested further has:
d) a static storage direction for nonvolatile storage of the initialization data that are fed by means of the storage signal and can be stored in the register device.

2. Apparatus according to claim 1, wherein the register device comprises a mode register unit.

3. Apparatus according to claim 1, wherein the register device comprises at least one extended mode register unit.

4. Apparatus according to claim 1, wherein the circuit unit to be tested is a DRAM memory.

5. Apparatus according to claim 1, wherein the static storage device for nonvolatile storage of the initialization data that are fed by means of the storage signal is constructed identically to the register device.

6. Apparatus according to claim 1, wherein the static storage direction has a mode register buffer storage unit for buffer-storing mode register initialization data.

7. Apparatus according to claim 1, wherein the static storage direction has at least one extended mode register buffer storage unit for buffer-storing extended mode register initialization data.

8. Method for testing a circuit units to be tested by means of a test system, having the following steps:
a) switching-on of the circuit unit to be tested by means of a switch-on unit;
b) storing of initialization data that are fed by means of a storage signal in a register device of the circuit unit to be tested;
c) controlling of a storage of the initialization data in the register device by means of a storage control signal provided by a control unit; and
d) testing of the circuit unit to be tested by means of a test procedure prescribed by the test system,
wherein the method further comprises the following step:
e) storing that is nonvolatile of the initialization data that are fed by means of the storage signal by means of a static storage direction.

9. Method according to claim 8, wherein the initialization data stored in the static storage device are transmitted directly into the register device in the event of a second and further test procedures for testing the circuit unit to be tested.

10. Method according to claim 8, wherein the static storage device stores the initialization data that are fed by means of the storage signal in nonvolatile fashion and in a manner arranged identically to the storage in the register device.

11. Method according to claim 8, wherein initialization signals are fed to the register device from the static storage device after the circuit unit to be tested has been switched on by means of the switch-on unit.

12. Method according to claim 8, wherein the storage signal fed to the circuit unit to be tested via a storage signal terminal unit is mirrored into the static storage device.

13. Method according to claim 8, wherein the register device is automatically set after the circuit unit to be tested has been switched on.

14. Method according to claim 8, wherein the static storage direction for nonvolatile storage of the initialization data that are fed by means of the storage signal and can be stored in the register device is controlled by means of the storage control signal.
